(19) United States
(12) Patent Application Publication
(10) Pub. No.: US 2026/0164649 A1
(43) Pub. Date: Jun. 11, 2026

(54) SEMICONDUCTOR DEVICE AND METHOD OF FABRICATING THE SAME

(71) Applicant: Samsung Electronics Co., Ltd., Suwon-si (KR)

(72) Inventors: Cheolmin SHIN, Suwon-si (KR); Jinwoo PARK, Suwon-si (KR); HYUNKYUNG BAE, Suwon-si (KR); SEONGMIN SON, Suwon-si (KR); KYU-HA LEE, Suwon-si (KR); TAESEONG KIM, Suwon-si (KR); HO-JIN LEE, Suwon-si (KR); DONG-CHAN LIM, Suwon-si (KR)

(21) Appl. No.: 19/268,628

(22) Filed: Jul. 14, 2025

(30) Foreign Application Priority Data
Dec. 10, 2024 (KR) 10-2024-0182956

(51) Int. Cl. H10B 12/00

(52) U.S. Cl. CPC H10B 12/50; H10B 12/09; H10B 12/315; H10B 12/482; H10B 12/488

(57) ABSTRACT

Disclosed are semiconductor devices and their fabrication methods. The semiconductor device comprises a first subsidiary integrated circuit, an upper dielectric layer that covers the first subsidiary integrated circuit, a polishing barrier layer on the upper dielectric layer, a bonding layer on the polishing barrier layer, and a substrate on the bonding layer. The upper dielectric layer and the bonding layer comprise a first material. The polishing barrier layer comprises a second material having a polishing selectivity with respect to the first material.

### CROSS-REFERENCE TO RELATED APPLICATION

This application claims priority under 35 U.S.C. § 119 to Korean Patent Application No. 10-2024-0182956 filed on Dec. 10, 2024 in the Korean Intellectual Property Office, the disclosure of which is hereby incorporated by reference in its entirety.

### BACKGROUND

The present inventive concepts relate to a semiconductor device and a method of fabricating the same.

With the development of the electronic industry, electronic products have increasing demands for high performance, high speed, and compact size. It is necessary that a semiconductor chip become small in size to cope with this trend. As one of various semiconductor processes to meet these demands, a back-grinding process is used to thin or remove a bare wafer (or sacrificial wafer). In the back-grinding process, cracks may occur to cause a reduction in yield.

### SUMMARY

Some embodiments of the present inventive concepts provide a semiconductor device with improved reliability.

Some embodiments of the present inventive concepts provide a method of fabricating a semiconductor device capable of suppressing crack and increasing yield.

The object of the present inventive concepts is not limited to the mentioned above, and other objects which have not been mentioned above will be clearly understood to those skilled in the art from the following description.

According to some embodiments of the present inventive concepts, a semiconductor device may comprise: a first subsidiary integrated circuit; an upper dielectric layer that covers the first subsidiary integrated circuit; a polished barrier layer on the upper dielectric layer; a bonding layer on the polished barrier layer; and a substrate on the bonding layer. The upper dielectric layer and the bonding layer may comprise a first material. The polished barrier layer may comprise a second material having a polishing selectivity with respect to the first material.

According to some embodiments of the present inventive concepts, a semiconductor device may comprise: a first subsidiary integrated circuit; an upper dielectric layer that covers the first subsidiary integrated circuit; a polished barrier layer on the upper dielectric layer; a bonding layer on the polished barrier layer; and a substrate on the bonding layer. The polished barrier layer may comprise a first barrier pattern and a second barrier pattern that are spaced apart from each other. The first barrier pattern may have a first width in a first direction. The second barrier pattern may have a second width in the first direction, the second width being different from the first width.

According to some embodiments of the present inventive concepts, a semiconductor device may comprise: a subsidiary integrated circuit; an upper dielectric layer that covers the subsidiary integrated circuit; a polished barrier layer on the upper dielectric layer; a bonding layer on the polished barrier layer; and a substrate on the bonding layer. The subsidiary integrated circuit may comprise: an active pattern elongated in a direction perpendicular to a bottom surface of the substrate and comprising a first end and a second end that are spaced apart from each other; a word line on a lateral surface of the active pattern and extending in a first direction parallel to the bottom surface of the substrate; a bit line connected to the first end of the active pattern and extending in a second direction crossing to the first direction; and a capacitor connected to the second end of the active pattern. The polished barrier layer comprises a plurality of barrier patterns that are spaced apart from each other. The plurality of barrier patterns includes first barrier patterns and second barrier patterns. Each barrier pattern is spaced apart from adjacent barrier patterns. Each of the first barrier patterns has a first width. Each of the second barrier patterns has a second width different from the first width. The capacitor overlaps at least one barrier pattern selected from the plurality of barrier patterns. The plurality of barrier patterns are spaced apart from each other at the same interval.

According to some embodiments of the present inventive concepts, a method of fabricating a semiconductor device may comprise: manufacturing a plurality of subsidiary integrated circuits on a first wafer that comprise a main region, a peripheral region that surrounds the main region, and an edge region that surrounds the peripheral region; forming on the first wafer an upper dielectric layer that covers the subsidiary integrated circuits; forming a preliminary polishing barrier layer on the upper dielectric layer, wherein the preliminary polishing barrier layer comprises a plurality of first preliminary barrier patterns on the main region, a plurality of second preliminary barrier patterns on the peripheral region, and a plurality of third preliminary barrier patterns on the edge region; forming a gap-fill layer to fill a space between the first, second, and third preliminary barrier patterns, the gap-fill layer covering the preliminary polishing barrier layer; performing a chemical mechanical polishing process to partially remove the gap-fill layer on the preliminary polishing barrier layer and to form polished barrier layer including first, second, and third barrier patterns, and to form a plurality of gap-fill patterns between the first, second, and third barrier patterns; stacking a bonding layer on the polished barrier layer; bonding a second wafer to the bonding layer; performing a trimming process to remove the edge region of the first wafer, the upper dielectric layer that overlaps the edge region of the first wafer, portions of the third barrier patterns and the gap-fill patterns, and a portion of the bonding layer; and removing the first wafer.

### BRIEF DESCRIPTION OF DRAWINGS

FIG. 1 illustrates a cross-sectional view showing a semiconductor device according to some embodiments of the present inventive concepts.

FIG. 2A illustrates an enlarged view showing section P1 of FIG. 1.

FIG. 2B illustrates a plan view showing a circuit structure of FIG. 1.

FIG. 3 illustrates a cross-sectional view showing a semiconductor device according to some example embodiments of the present inventive concepts.

FIG. 4 illustrates a cross-sectional view showing a semiconductor device according to some embodiments of the present inventive concepts.

FIG. 5 illustrates a cross-sectional view showing a semiconductor device according to some embodiments of the present inventive concepts.

FIGS. 6A to 6E illustrate plan views showing polishing barrier structures according to some embodiments of the present inventive concepts.

FIGS. 7A and 7B illustrate plan views showing a first wafer according to some embodiments of the present inventive concepts.

FIGS. 8A to 8I illustrate cross-sectional views showing a method of fabricating a semiconductor device according to some embodiments of the present inventive concepts.

FIGS. 9A and 9B illustrate plan views showing polishing barrier patterns formed on a first wafer according to some embodiments of the present inventive concepts.

FIG. 10A illustrates an enlarged view showing section P2 of FIG. 8D.

FIG. 10B illustrates an enlarged view showing section P2 of FIG. 8F.

FIG. 10C illustrates an enlarged view showing section P2 of FIG. 8G.

FIGS. 11A and 11B illustrate plan views showing a second wafer when a dicing process is performed.

### DETAILED DESCRIPTION OF EMBODIMENTS

It will be hereinafter discussed that a semiconductor device and a method of fabricating the same are provided according to some embodiments of the present inventive concepts, in conjunction with the accompanying drawings. In this description, such terms as “first” and “second” may be used to simply distinguish identical or similar components from each other, and the sequence of such terms may be changed in accordance with the order of mention. In this description, terms indicating positions such as upper, lower, bottom surface, and top surface may be interchangeably used depending on the point of view.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality.

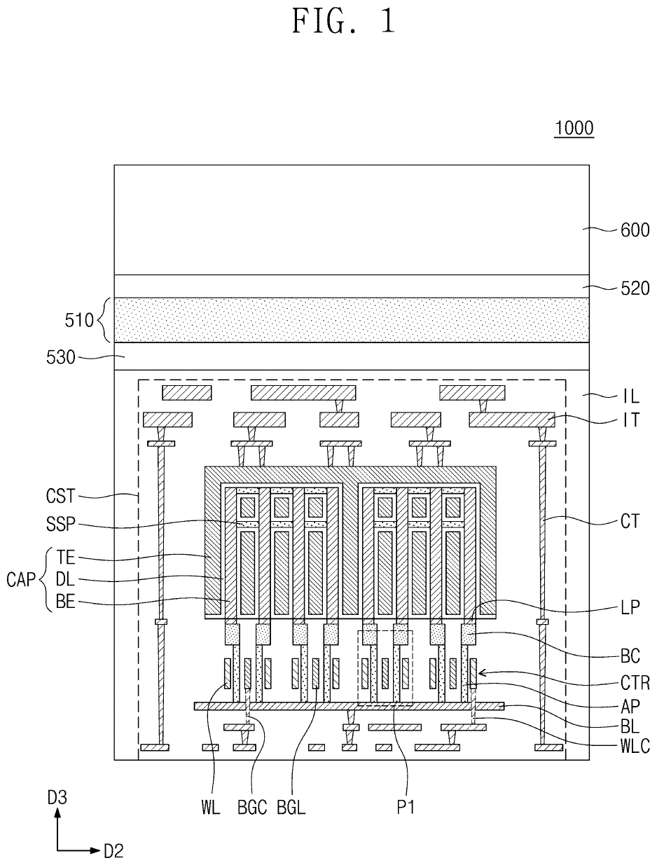

FIG. 1 illustrates a cross-sectional view showing a semiconductor device according to some embodiments of the present inventive concepts.

Referring to FIG. 1, a semiconductor device 1000 according to the present embodiment may include a first circuit structure CST, and may also include an upper dielectric layer 530, a polishing barrier structure (or polishing barrier) 510, a bonding layer 520, and a support substrate 600 that are sequentially stacked on the first circuit structure CST. The semiconductor device 1000 may be a semiconductor chip, for example, singulated from a wafer. The first circuit structure CST may include at least one selected from memory cells, peripheral circuits, and logic circuits. The first circuit structure CST may include at least one selected from transistors, wiring lines, resistor devices, capacitors, and memory cells. The transistors included in the first circuit structure CST may employ transistor technologies, such as planar field effect transistor (planar FET), FinFET, vertical FET, vertical channel transistor (VCT), buried channel array transistor (BCAT), gate all around field effect transistor (GAAFET), or multi-bridge channel field effect transistor (MBCFET). The memory cells may have various types of memory cell structures used in memory technologies, such as dynamic random access memory (DRAM), ferroelectric random access memory (FRAM), magnetic random access memory (MRAM), phase change random access memory (PRAM), resistive random access memory (ReRAM), static random access memory (SRAM), and vertical NAND (VNAND). A detailed example of the first circuit structure CST will be discussed below.

The upper dielectric layer 530 may cover the first circuit structure CST. Each of the upper dielectric layer 530 and the bonding layer 520 may have a single-layered or multi-layered structure of at least one selected from silicon oxide, silicon nitride, and SiCN. For example, the upper dielectric layer 530 and the bonding layer 520 may be formed of a first dielectric material. In the present embodiment, the polishing barrier structure 510 may be formed of a single layer including a second dielectric material having a polishing selectivity with respect to the first dielectric material. The polishing selectivity may refer to a selectivity in a chemical mechanical polishing (CMP) process. The polishing selectivity may be the relative removal rates of different materials, and a material is removed substantially at a different rate compared to another material under the same CMP conditions. For example, when an element has a selectivity with respect to another element, the difference of the selectivity is sufficiently high such that the desirable thickness difference ΔTH or the control of the edge roll-off (discussed later) may be achieved.

The first dielectric material may be, for example, silicon oxide. The second dielectric material may be, for example, silicon nitride. The support substrate 600 may be a monocrystalline silicon substrate, a silicon-on-insulator (SOI) substrate, a semiconductor substrate, or a dielectric substrate. The polishing barrier structure 510 may cover a front surface of the first circuit structure CST and vertically overlap the first circuit structure CST. The polishing barrier structure 510 may have a thickness of 10 Å to 10,000 Å.

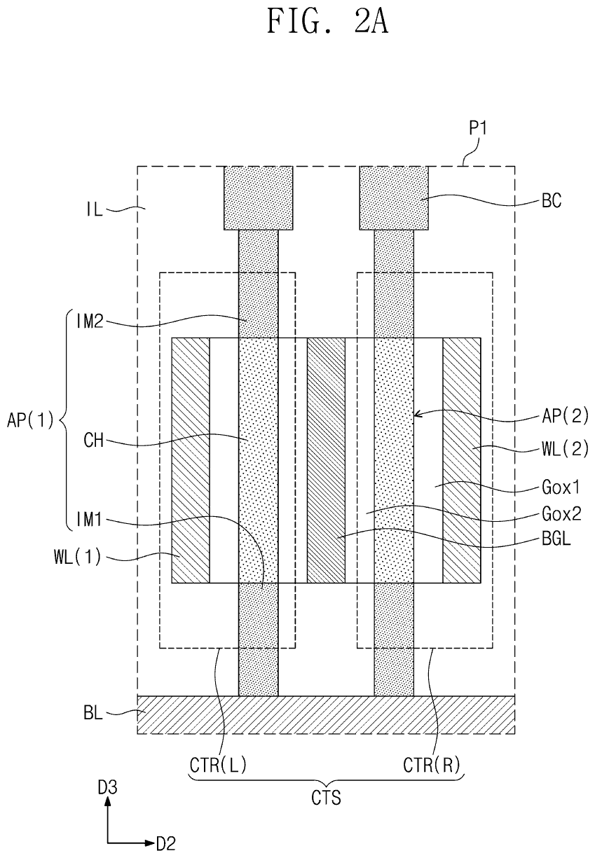

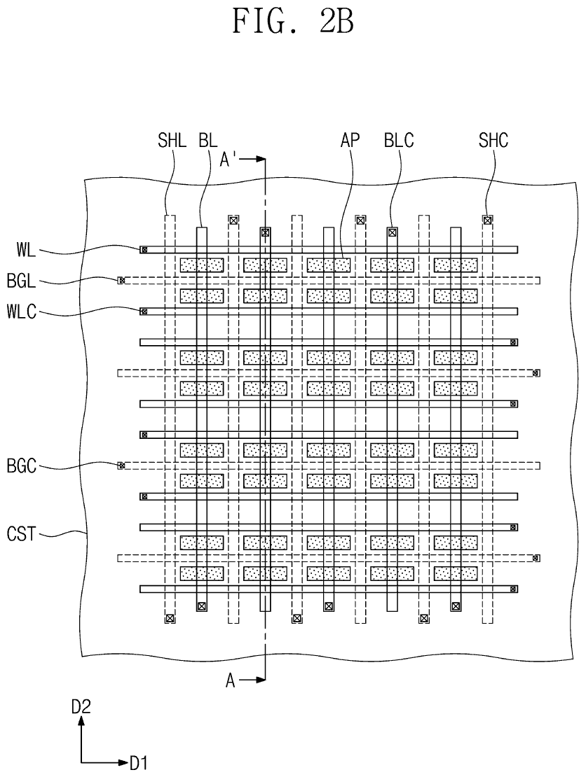

FIG. 2A illustrates an enlarged view showing section P1 of FIG. 1. FIG. 2B illustrates a plan view showing a circuit structure of FIG. 1.

Referring to FIGS. 1, 2A, and 2B, the first circuit structure CST may include bit lines BL, shield lines SHL, word lines WL, back-gate lines BGL, cell transistors CTR, capacitors CAP, contact plugs CT, wiring lines IT, and an interlayer dielectric layer IL. The interlayer dielectric layer IL may have a single-layered or multi-layered structure of at least one selected from silicon oxide, silicon nitride, silicon oxynitride, and porous dielectric.

The bit lines BL and the shield lines SHL may extend in a second direction D2 and may be spaced apart from each other in a first direction D1. The shield lines SHL may be correspondingly interposed between the bit lines BL. The bit lines BL and the shield lines SHL may be located at the same level.

A bit-line contact plug BLC may penetrate a portion of the interlayer dielectric layer IL to come into connection with the bit lines BL. A shield-line contact plug SHC may penetrate a portion of the interlayer dielectric layer IL to come into connection with the shield lines SHL. A word-line contact plug WLC may penetrate a portion of the interlayer dielectric layer IL to come into connection with the word line WL. A back-gate contact plug BGC may penetrate a portion of the cell interlayer dielectric layer IL to come into connection with the back-gate line BGL.

The cell transistors CTR may include their respective active patterns AP. The active patterns AP may include a pair of first and second active patterns AP(1) and AP(2) that are adjacent to each other in the second direction D2. A channel region CH and first and second impurity regions IM1 and IM2 may be disposed on each of the active patterns AP. The first impurity regions IM1 of the active patterns AP may be in contact with the bit lines BL. The second impurity regions IM2 of the active patterns AP may be in contact with storage node contacts BC.

The word lines WL may include a pair of first and second word lines WL(1) and WL(2) that are adjacent to each other in the second direction D2. The first word line WL(1) may be adjacent to the channel region CH of the first active pattern AP(1). The second word line WL(2) may be adjacent to the channel region CH of the second active pattern AP(2).

First gate dielectric layers Gox1 may be disposed between the first and second word lines WL(1) and WL(2) and the first and second active patterns AP(1) and AP(2). The first gate dielectric layers Gox1 may extend in the first direction D1 parallel to the first and second word lines WL(1) and WL(2).

The back-gate line BGL may be interposed between a pair of first and second active patterns AP(1) and AP(2). The word lines WL and the back-gate lines BGL may extend along the first direction D1. A second gate dielectric layer Gox2 may be disposed between the back-gate line BGL and the first and second active patterns AP(1) and AP(2). The first gate dielectric layers Gox1 and the second gate dielectric layer Gox2 may each be formed of, for example, a single or multiple layer including at least one selected from a silicon oxide layer, a silicon oxynitride layer, and a high-k dielectric layer whose dielectric constant is greater than that of a silicon oxide layer. The high-k dielectric layer may be formed of metal oxide or metal oxynitride. For example, the high-k dielectric layer possibly used as the first and second gate dielectric layers Gox1 and Gox2 may be formed of HfO2, HfSiO, HfSiON, HfTaO, HfTiO, HfZrO, ZrO2, Al2O3, or any combination thereof, but the present inventive concepts are not limited thereto. According to some embodiments, the second gate dielectric layer Gox2 may be formed of a single or multiple layer including a dielectric material whose dielectric constant is less than that of a silicon oxide layer. For example, the second gate dielectric layer Gox2 may include SiOCH or an air gap.

A portion of the first word line WL(1) and its adjacent first active pattern AP(1) may constitute a left cell transistor CTR(L). A portion of the second word line WL(2) and its adjacent second active pattern AP(2) may constitute a right cell transistor CTR(R). The left cell transistor CTR(L) and the right cell transistor CTR(R) may constitute a cell transistor structure CTS.

The bit lines BL and the shield lines SHL may each include one or more of impurity-doped polysilicon, conductive metal nitride (e.g., titanium nitride or tantalum nitride), and metal (e.g., tungsten, titanium, or tantalum).

The active patterns AP may be formed of a monocrystalline semiconductor material, an oxide semiconductor material, or a two-dimensional semiconductor material. The oxide semiconductor material may be indium-gallium-zinc oxide. The two-dimensional semiconductor material may be MoS2, WS2, MoSe2, or WSe2. For example, the active patterns AP may be formed of monocrystalline silicon.

The first and second impurity regions IM1 and IM2 may be areas doped with N-type or P-type impurities in the first and second active patterns AP(1) and AP(2). The channel region CH may not be doped with impurities or may be doped with impurities whose conductivity type is different from that of impurities doped in the first and second impurity regions IM1 and IM2.

The channel regions CH of the first and second active patterns AP(1) and AP(2) may be controlled by the first and second word lines WL(1) and WL(2) and the back-gate lines BGL when the semiconductor device 1000 is operated.

The back-gate lines BGL may be disposed spaced apart at a regular interval from each other in the second direction D2 on the bit lines BL. The back-gate lines BGL may extend in the first direction D1, while running across the bit lines BL. The first word line WL(1), the second word line WL(2), and the back-gate lines BGL may include, for example, doped polysilicon, conductive metal nitride (e.g., titanium nitride or tantalum nitride), metal (e.g., tungsten, titanium, or tantalum), conductive metal silicide, conductive metal oxide, or any combination thereof.

The back-gate lines BGL may be provided with a negative voltage when a semiconductor memory device is operated, and may increase a threshold voltage of a vertical channel transistor. For example, the fineness of the vertical channel transistor may reduce a threshold voltage, and thus leakage current characteristics may be prevented from being deteriorated.

Storage node contacts BC may penetrate a portion of the interlayer dielectric layer IL to come into coupling with the first and second active patterns AP(1) and AP(2). The storage node contacts BC may each have a lower width greater than an upper width. Neighboring storage node contacts BC may be divided from each other. When viewed in plan view, each of the storage node contacts BC may have a circular shape, an oval shape, a rectangular shape, a square shape, a rhombic shape, a hexagonal shape, or any other suitable shape. The storage node contacts BC may be arranged in a matrix shape along the first direction D1 and the second direction D2. The storage node contacts BC may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present inventive concepts are not limited thereto.

Landing pads LP may be disposed on the storage node contacts BC. When viewed in plan view, each of the landing pads LP may have a circular shape, an oval shape, a rectangular shape, a square shape, a rhombic shape, a hexagonal shape, or any other suitable shape. The landing pads LP may completely or partially vertically overlap the storage node contacts BC. When viewed in plan view, the landing pads LP may be arranged in a matrix shape along the first direction D1 and the second direction D2. Alternatively, the landing pads LP may be arranged in a honeycomb shape when viewed in plan view. The landing pads LP may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present inventive concepts are not limited thereto.

Bottom electrodes BE may be correspondingly disposed on the landing pads LP. The bottom electrodes BE may be correspondingly electrically connected to the first and second active patterns AP(1) and AP(2). Each of the bottom electrodes BE may have a pillar shape or a hollow cup shape.

The bottom electrodes BE may be disposed in a honeycomb shape or a matrix shape along the first direction D1 and the second direction D2. The bottom electrodes BE may completely or partially overlap the landing pads LP. The bottom electrodes BE may be entirely or partially in contact with bottom surfaces of the landing pads LP. A constant interval may be provided between the bottom electrodes BE. The bottom electrodes BE may include at least one selected from impurity-doped silicon, metal, metal oxide, and metal nitride. For example, the bottom electrodes BE may include a titanium nitride layer.

The bottom electrodes BE may have part of their lower sidewalls in contact with support patterns SSP. The support patterns SSP may prevent collapse of the bottom electrodes BE. When viewed in plan view, the support patterns SSP may have a mesh shape or a plate shape in which a plurality of perforations are formed. The support patterns SSP may be formed of either one layer or two or more layers. The support patterns SSP may be formed of a single or multiple layer including at least one selected from, for example, a silicon nitride (SiN) layer, a silicon boronitride (SiBN) layer, and a silicon carbonitride (SiCN) layer.

A dielectric layer DL may conformally cover the bottom electrodes BE and the support patterns SSP. The dielectric layer DL may be formed of a single or multiple layer including at least one selected from, for example, a silicon oxide layer or a metal oxide layer such as an aluminum oxide layer having a material whose dielectric constant is greater than that of a silicon oxide layer. The dielectric layer DL may have a single-layered or a multi-layered structure of at least one selected from a ferroelectric layer and an antiferroelectric layer. A top electrode TE may cover a bottom surface of the dielectric layer DL. The top electrode TE may be formed to have a single-layered or multi-layered structure of at least one selected from a titanium nitride layer, a tungsten layer, an impurity-doped polysilicon layer, and an impurity-doped silicon-germanium layer. The top electrode TE may have a sidewall aligned with that of the dielectric layer DL. The bottom electrodes BE, the dielectric layer DL, and the top electrode TE may constitute capacitors CAP. The bit lines BL, the shield lines SHL, the word lines WL, the back-gate lines BGL, and the top electrode TE may be connected to one or more of the wiring lines IT.

In the present inventive concepts, the polishing barrier structure 510 may be utilized to achieve a desired degree (amount) of edge roll-off. Accordingly, the semiconductor device 1000 is less likely to suffer from being cracked, and the reliability of the semiconductor device 1000 may be improved. The edge roll-off is a thinning effect occurring at the edge of a wafer during a chemical mechanical planarization (CMP) process, which can lead to increased susceptibility to edge cracking.

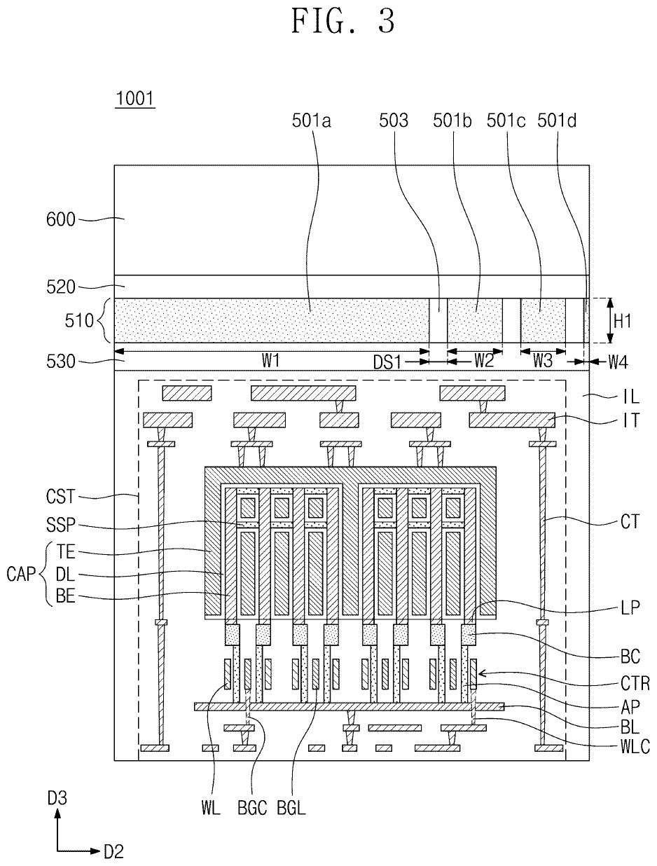

FIG. 3 illustrates a cross-sectional view showing a semiconductor device according to some embodiments of the present inventive concepts.

Referring to FIG. 3, in a semiconductor device 1001 according to the present embodiment, the polishing barrier structure 510 may include polishing barrier patterns 501a to 501d and gap-fill patterns 503 between the polishing barrier patterns 501a to 501d. The gap-fill patterns 503 may have a single-layered or multi-layered structure of at least one selected from silicon oxide, silicon nitride, and SiCN. For example, the gap-fill patterns 503 may be formed of the same dielectric material as the upper dielectric layer 530 and the bonding layer 520. The polishing barrier patterns 501a to 501d may be formed of a second dielectric material having a polishing selectivity with respect to the first dielectric material. The first dielectric material may be, for example, silicon oxide. The second dielectric material may be, for example, silicon nitride. The polishing barrier patterns 501a to 501d may include first to fourth polishing barrier patterns 501a to 501d that are spaced apart from each other. The present embodiments discloses. by way of example. four polishing barrier patterns 501a to 501d, but the present inventive concepts are not limited thereto and the number of polishing barrier patterns 501a to 501d may be three or fewer or five or more.

The first to fourth polishing barrier patterns 501a to 501d may be arranged side-by-side along the second direction D2. The first to fourth polishing barrier patterns 501a to 501d may be spaced apart from each other at a first interval DS1. The first to fourth polishing barrier patterns 501a to 501d may each have a width that decreases in order, along the second direction D2. For example, the first polishing barrier pattern 501a may have a first width W1. The second polishing barrier pattern 501b may have a second width W2 less than the first width W1. The third polishing barrier pattern 501c may have a third width W3 less than the second width W2. The fourth polishing barrier pattern 501d may have a fourth width W4 less than the third width W3. The first and second polishing barrier patterns 501a and 501b may overlap the top electrode TE. Other configurations of the polishing barrier patterns may be identical or similar to those of the polishing barrier patterns discussed with reference to FIGS. 1 to 2B.

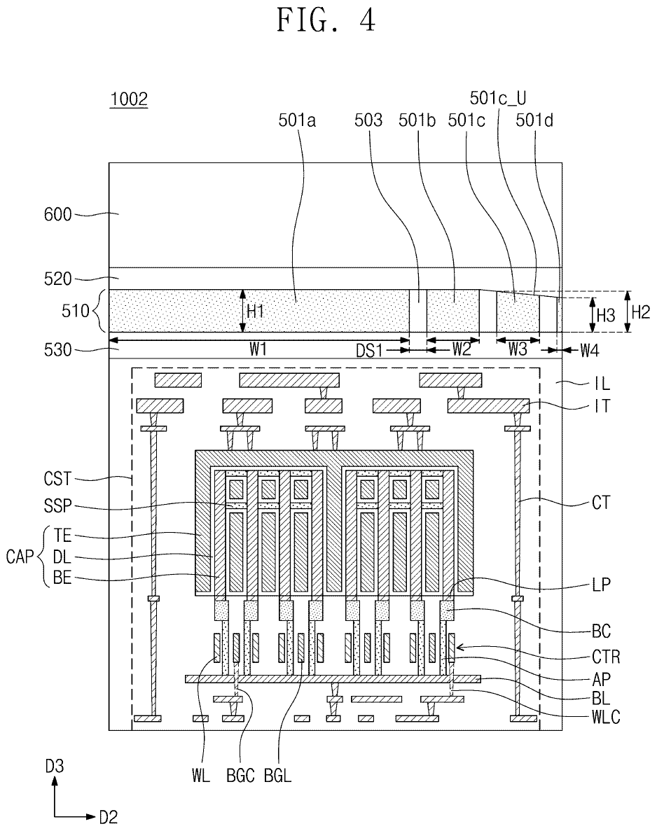

FIG. 4 illustrates a cross-sectional view showing a semiconductor device according to some embodiments of the present inventive concepts.

Referring to FIG. 4, in a semiconductor device 1002 according to the present embodiment, the polishing barrier structure (or polishing barrier layer) 510 may include polishing barrier patterns 501a to 501d and gap-fill patterns 503 between the polishing barrier patterns 501a to 501d. The first and second polishing barrier patterns 501a and 501b may have a first height H1. The first and second polishing barrier patterns 501a and 501b may have their flat top surfaces. The third polishing barrier pattern 501c may have an inclined top surface 501c_U. Unlike the example shown in FIG. 3 (where the height does not vary as indicated by H1), the height of the third polishing barrier pattern 501c may vary along the second direction D2 in FIG. 4. For example, the third polishing barrier pattern 501c may have a second height (an average height between a bottom and top of the third polishing barrier pattern 501c) H2 less than the first height (an average height between a bottom and top of the first and/or second polishing barrier patterns 501a and 501b) H1. The fourth polishing barrier pattern 501d may have a third height H3 less than the second height H2. A difference between the first height H1 and the third height H3 may range from 10 Å to 6,000 Å. The gap-fill pattern 503 positioned between the third and fourth polishing barrier patterns 501c and 501d may have an inclined top surface. A thickness of the bonding layer 520 on the third and fourth polishing barrier patterns 501c and 501d may be greater than a thickness of the bonding layer 520 on the first and second polishing barrier patterns 501a and 501b. Other configurations of the polishing barrier patterns may be identical or similar to those of the polishing barrier patterns discussed above with reference to FIG. 3.

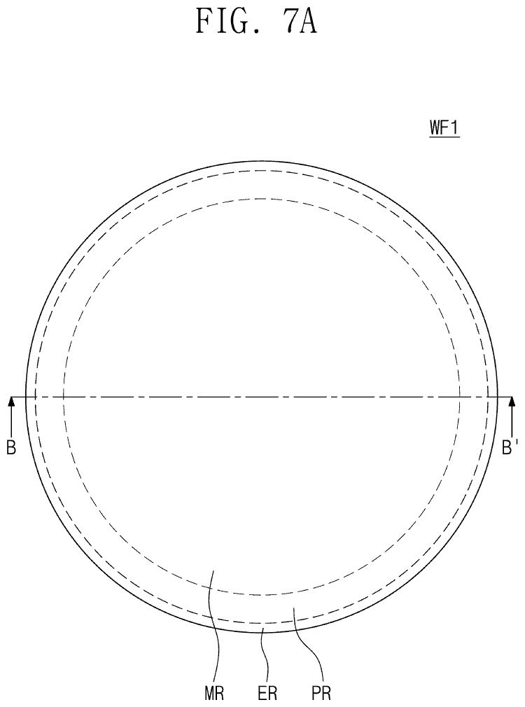

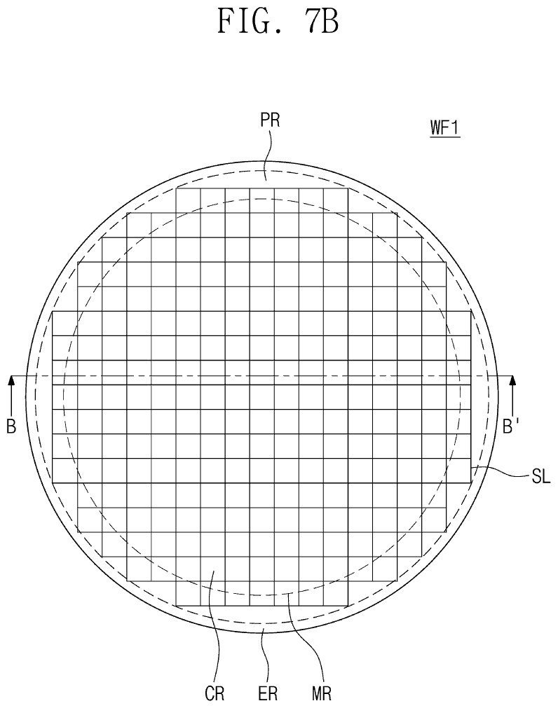

Each of the embodiments described with reference to FIGS. 1, 3, and 4 may correspond to a part of a particular one among the wafers described later with reference to FIGS. 7A, 7B, 8A to 8I, 9A, 9B, 11A, and 11B.

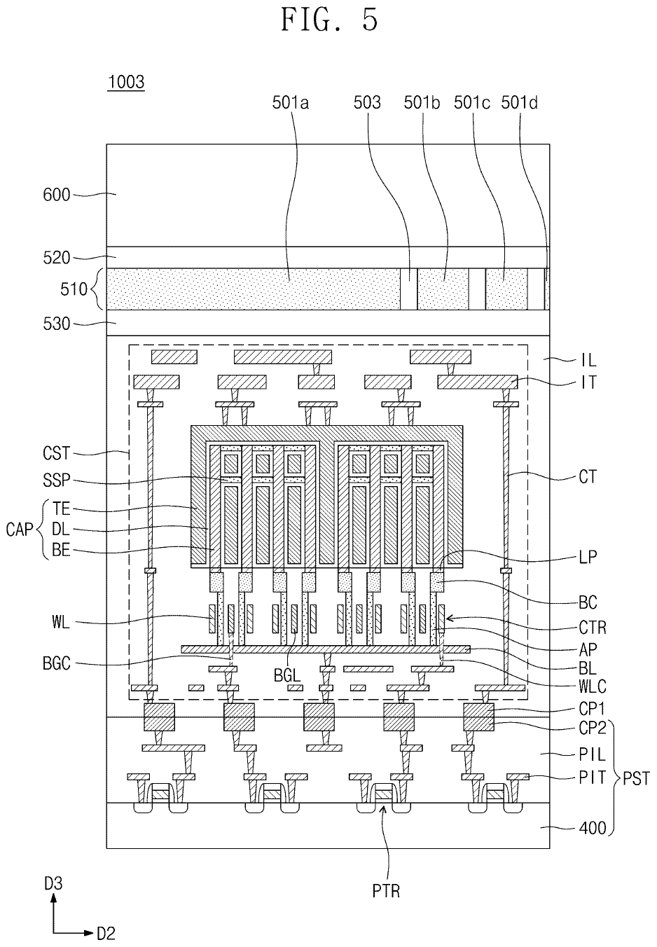

FIG. 5 illustrates a cross-sectional view showing a semiconductor device according to some embodiments of the present inventive concepts.

Referring to FIG. 5, a semiconductor device 1003 according to the present embodiment may further include a second circuit structure (or second subsidiary integrated circuit) PST disposed below the first circuit structure (or first subsidiary integrated circuit) CST described with reference to FIG. 3. The first and second subsidiary integrated circuits CST and PST may be electrically connected to each other, thereby forming an integrated circuit as a semiconductor device. For example, the first circuit structure CST may be or include a cell structure. The second circuit structure PST may be or include a peripheral circuit structure. First connection pads CP1 may be connected to some of the contact plugs CT and the wiring lines IT. The first connection pads CP1 may be disposed below the first circuit structure CST. In some embodiments, the first circuit structure CST may include the first connection pads CP1.

The second circuit structure PST may include a peripheral substrate 400, and may also include peripheral transistors PTR, peripheral wiring lines PIT, a peripheral interlayer dielectric layer PIL, and second connection pads CP2 that are disposed on the peripheral substrate 400. The second connection pads CP2 may be disposed on a top end of the peripheral interlayer dielectric layer PIL. The second connection pads CP2 may be in contact with corresponding first connection pads CP1 such that the first and second subsidiary integrated circuits CST and PST may be electrically connected to each other, thereby forming a single integrated circuit as part of a single semiconductor device (e.g., chip). The first connection pads CP1 and the second connection pads CP2 may each include copper. No interface may be observed between the first and second connection pads CP1 and CP2 that are in contact with each other, and the first and second connection pads CP1 and CP2 in contact with each other may constitute a single unitary piece. The bit lines BL, the shield lines SHL, the word lines WL, the back-gate lines BGL, and the top electrode TE may be electrically connected to the peripheral transistors PTR through the first and second connection pads CP1 and CP2 and the peripheral wiring lines PIT. Other configurations of the semiconductor device 1003 may be identical or similar to those of the semiconductor device 1001 discussed above with reference to FIG. 3.

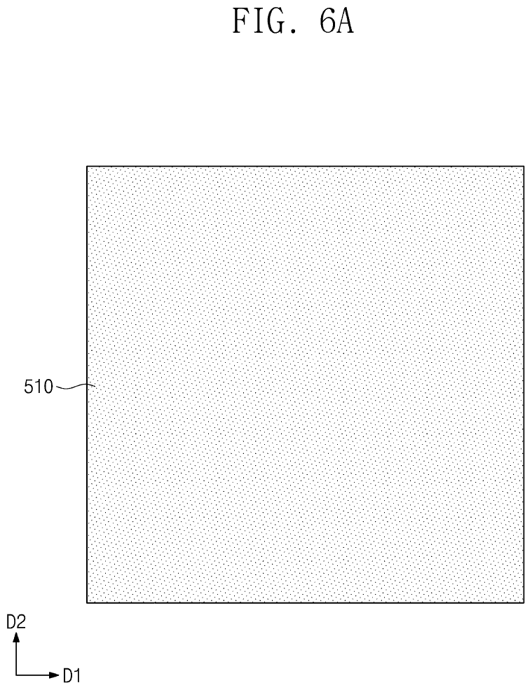

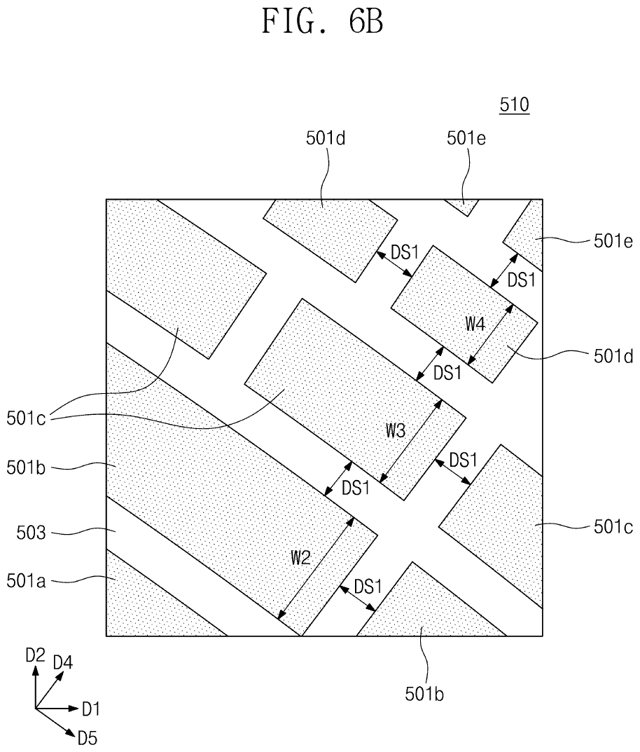

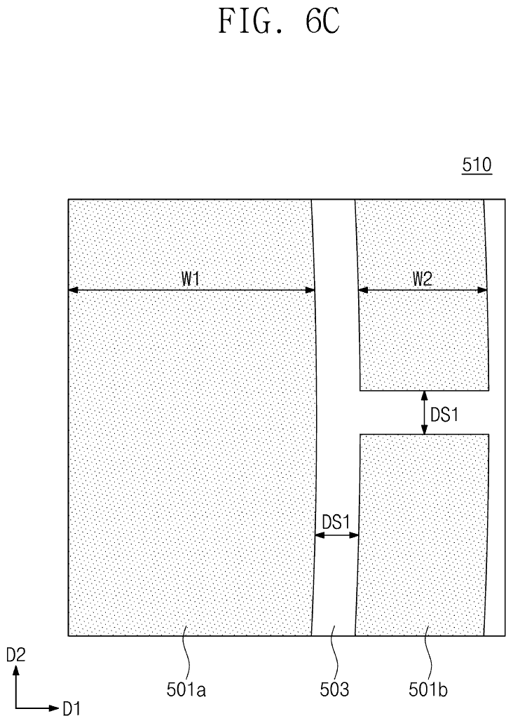

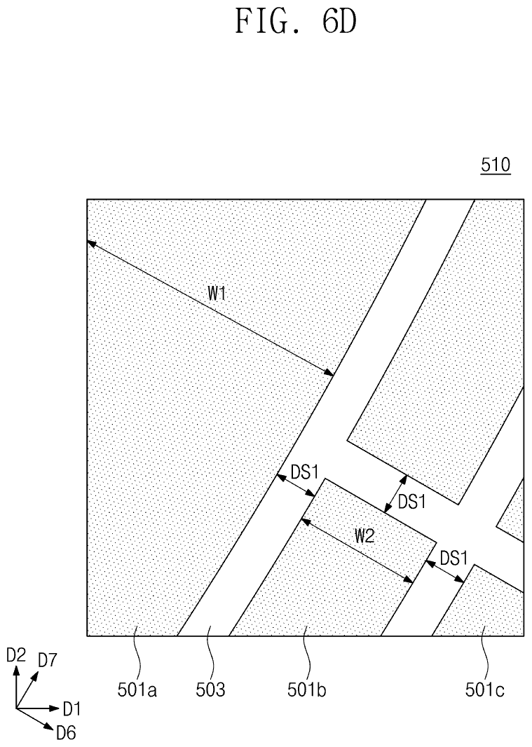

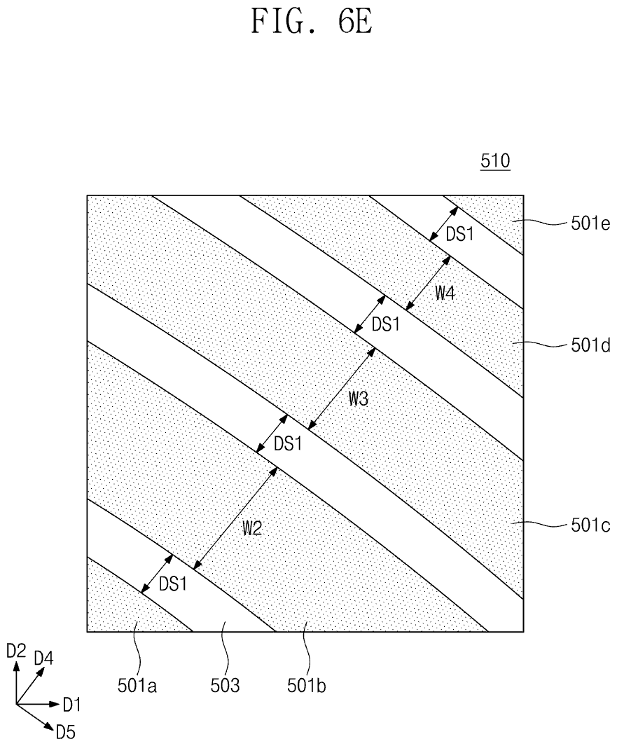

Although the polishing barrier layer 510 in FIG. 5 is illustrated as identical to that in FIG. 3, the invention is not limited thereto and it may be identical or similar to those described in FIGS. 1, 3, or 4. FIGS. 6A to 6E illustrate plan views showing polishing barrier structures according to some embodiments of the present inventive concepts.

Referring to FIG. 6A, the polishing barrier structure 510 may have a plate shape when viewed in plan view. The polishing barrier structure 510 of FIG. 6A may have a cross section that corresponds to that of the polishing barrier structure 510 depicted in FIG. 1.

Referring to FIG. 6B, the polishing barrier structure 510 may include first to fifth polishing barrier patterns 501a to 501e and a gap-fill pattern 503 interposed between the first to fifth polishing barrier patterns 501a to 501e. Each of the first to fifth polishing barrier patterns 501a to 501e may have a triangular shape, a tetragonal (or rectangular) shape, a pentagonal shape, or any other suitable polygonal shape as shown in FIG. 6B. The gap-fill pattern 503 may have a grid shape when viewed in plan view. The first to fifth polishing barrier patterns 501a to 501e may be spaced apart from each other at the same interval (e.g., a first interval DS1) in a fourth direction D4 and in a fifth direction D5. The first to fifth polishing barrier patterns 501a to 501e may be two-dimensionally arranged along the fourth direction D4 and the fifth direction D5. Each of the fourth direction D4 and the fifth direction D5 may intersect the first direction D1 and the second direction D2. The first polishing barrier pattern 501a may have a triangular shape when viewed in plan view.

The second polishing barrier patterns 501b may be arranged along the fifth direction D5 and spaced apart from each. When viewed in plan view, one of the second polishing barrier patterns 501b may have a pentagonal shape, and another of the second polishing barrier patterns 501b may have a triangular shape. One of the second polishing barrier patterns 501b may have a second width W2 in the fourth direction D4.

The third polishing barrier patterns 501c may be arranged along the fifth direction D5 and spaced apart from each other. When viewed in plan view, one of the third polishing barrier patterns 501c may have a pentagonal shape, and another of the third polishing barrier patterns 501c may have a tetragonal (or rectangular) shape. When viewed in plan view, still another of the third polishing barrier patterns 501c may have a triangular shape. Each of the third polishing barrier patterns 501c may have a third width W3 in the fourth direction D4 less than the second width W2.

The fourth polishing barrier patterns 501d may be arranged along the fifth direction D5 and spaced apart from each other. When viewed in plan view, one of the fourth polishing barrier patterns 501d may have a pentagonal shape, and another of the fourth polishing barrier patterns 501d may have a tetragonal (or rectangular) shape. Each of the fourth polishing barrier patterns 501d may have a fourth width W4 in the fourth direction D4 less than the third direction D3.

The fifth polishing barrier patterns 501e may be arranged along the fifth direction D5 and spaced apart from each other. When viewed in plan view, one of the fifth polishing barrier patterns 501e may have a triangular shape, and another of the fifth polishing barrier patterns 501e may have a pentagonal shape.

Alternatively, referring to FIG. 6C, the polishing barrier structure 510 may include first and second polishing barrier patterns 501a and 501b and a gap-fill pattern 503 interposed between the first and second polishing barrier patterns 501a and 501b. The first and second polishing barrier patterns 501a and 501b may be spaced apart from each other at a first interval DS1. When viewed in plan view, sidewalls (or edges) of the first and second polishing barrier patterns 501a and 501b may be partially rounded. When viewed in a cross section, the surface of at least one of the first and second polishing barrier patterns 501a and 501b may be inclined as described with reference to FIG. 4. The first polishing barrier pattern 501a may have a first width W1 in the first direction D1, and the first width W1 may be changed depending on position. The second polishing barrier patterns 501b may have a second width W2 in the first direction D1 less than the first width W1. The second polishing barrier patterns 501b may be spaced apart from each other in the second direction D2.

Alternatively, referring to FIG. 6D, the polishing barrier structure 510 may include first, second, and third polishing barrier patterns 501a, 501b, and 501c and a gap-fill pattern 503 interposed between the first to third polishing barrier patterns 501a to 501c. The first, second, and third polishing barrier patterns 501a, 501b, and 501c may be spaced apart from each other at a first interval DS1. When viewed in plan view, sidewalls (or edges) of the first and second polishing barrier patterns 501a and 501b may be partially rounded. When viewed in a cross section, the surface of at least one of the first and second polishing barrier patterns may be inclined as described with reference to FIG. 4. The first polishing barrier pattern 501a may have a first width W1 in a sixth direction D6 on a certain position, and the first width W1 may be changed depending on position. The second polishing barrier patterns 501b may have a second width W2 in the sixth direction D6 less than the first width W1.

Alternatively, referring to FIG. 6E, the polishing barrier structure 510 may include first to fifth polishing barrier patterns 501a to 501e and a gap-fill pattern 503 interposed between the first to fifth polishing barrier patterns 501a to 501e. Each of the second to fourth polishing barrier patterns 501b to 501d may have a bar shape that extends along the fifth direction D5. The polishing barrier patterns 501a to 501e may not be separated in the fifth direction D5, unlike those in FIG. 6B. The first to fifth polishing barrier patterns 501a to 501e may have their sidewalls that are partially rounded. When viewed in a cross section, the surface of at least one of the first and second polishing barrier patterns may be inclined as described with reference to FIG. 4. The first to fifth polishing barrier patterns 501a to 501e may be sequentially arranged along the fourth direction D4. Other configurations of the polishing barrier patterns may be identical or similar to those of the polishing barrier patterns discussed with reference to FIG. 6B.

The arrangement of the polishing barrier patterns and their relationship with the coordinate axes is not limited to the configuration shown in each of the FIG. 6B to 6E. For example, a set of polishing barrier patterns in each of the drawings may be rearranged in a manner where they are rotated by a rotation angle, while substantially maintaining the relationship among each polishing barrier pattern and the others.

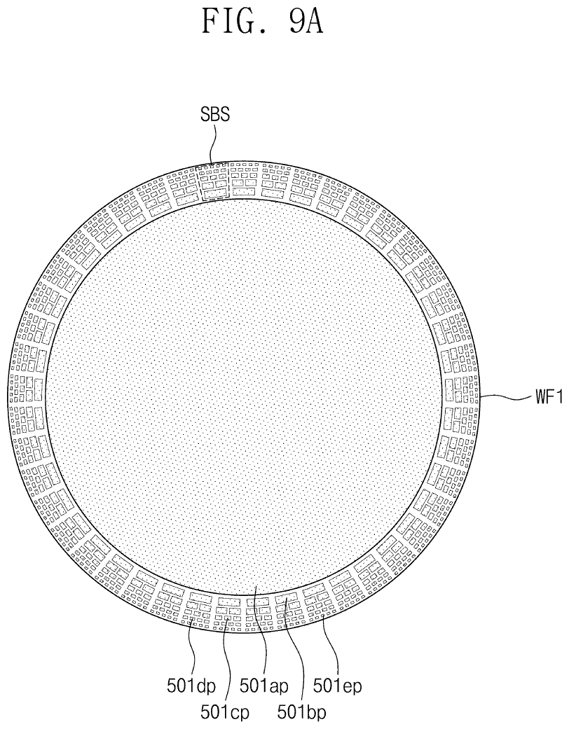

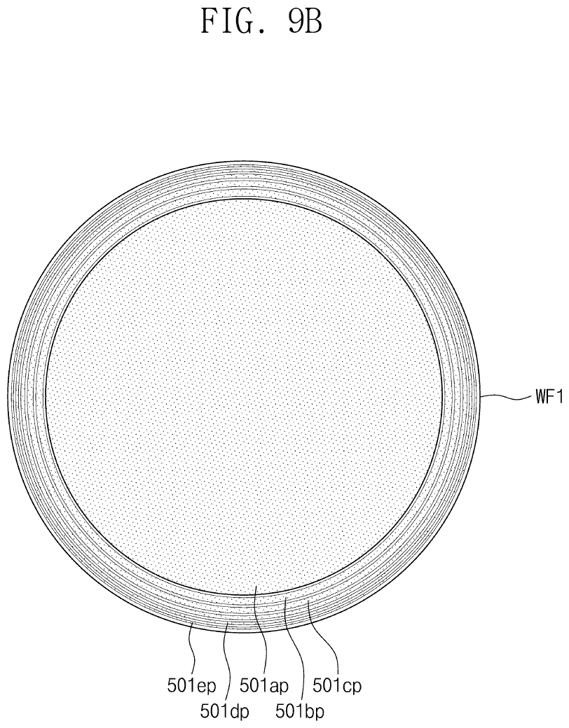

For example, FIG. 6D may substantially correspond to a rotated configuration of FIG. 6C such that all or some of the polishing barrier patterns (e.g., 501a and 501b) shown in FIG. 6C may be rearranged as if they are rotated clockwise substantially 45 degrees relative to an axis perpendicular to the surface of the drawing sheet. As a result, an arrangement of the polishing barrier patterns in FIG. 6D may be provided, though each of the polishing barrier patterns 501a and 501b in FIG. 6C may have a different shape from a corresponding one in FIG. 6C. In another example, the rotation angle may be substantially an angle other than 45 degrees. This rotational relationship may be better understood by those skilled in the art with reference to the embodiment shown in FIGS. 9A and 9B, where a concentric arrangement of the plurality of the polishing barrier structures 501 is described.

The plurality of the polishing barrier patterns respectively described with reference to FIGS. 6C and 6D may be a part of a particular one of the wafers described later with reference to FIGS. 7A, 7B, 8A to 8I, 9A, 9B, 11A and 11B.

The following will describe a method of fabricating a semiconductor device according to the present inventive concepts.

FIGS. 7A and 7B illustrate plan views showing a first wafer according to some embodiments of the present inventive concepts.

Referring to FIGS. 7A and 7B, a first wafer WF1 may be prepared. As illustrated in FIG. 7A, the first wafer WF1 may include a main region MR, a peripheral region PR that surrounds the main region MR, and an edge region ER that surrounds the peripheral region PR. A width of the edge region ER may range from 0.5 mm to 3 mm, for example, 0.5 mm to 1.8 mm. A width of the peripheral region PR may range from 5 mm to 7 mm.

As illustrated in FIG. 7B, the first wafer WF1 may include chip regions CR and a scribe lane SL between the chip regions CR. Most of the chip regions CR may be disposed on the main region MR. A portion of the chip regions CR may overlap the peripheral region PR.

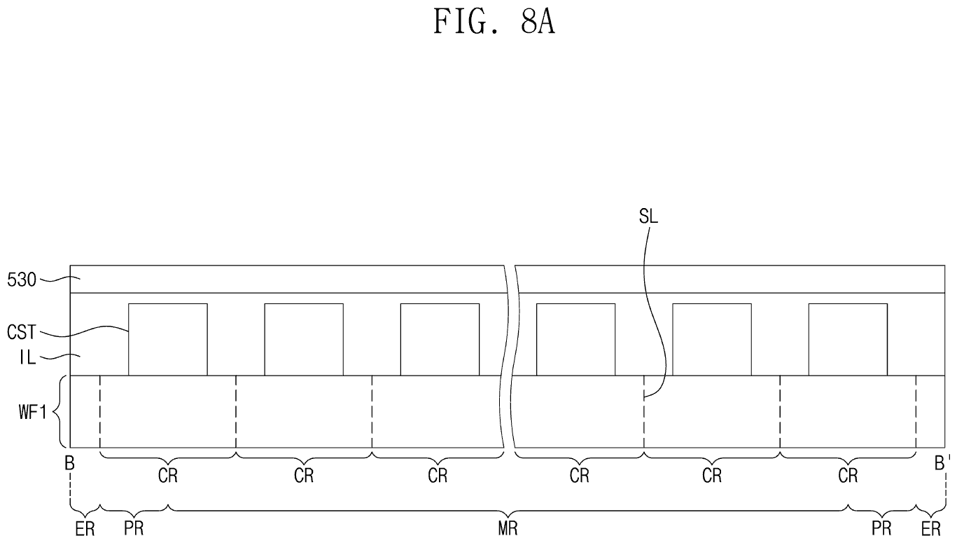

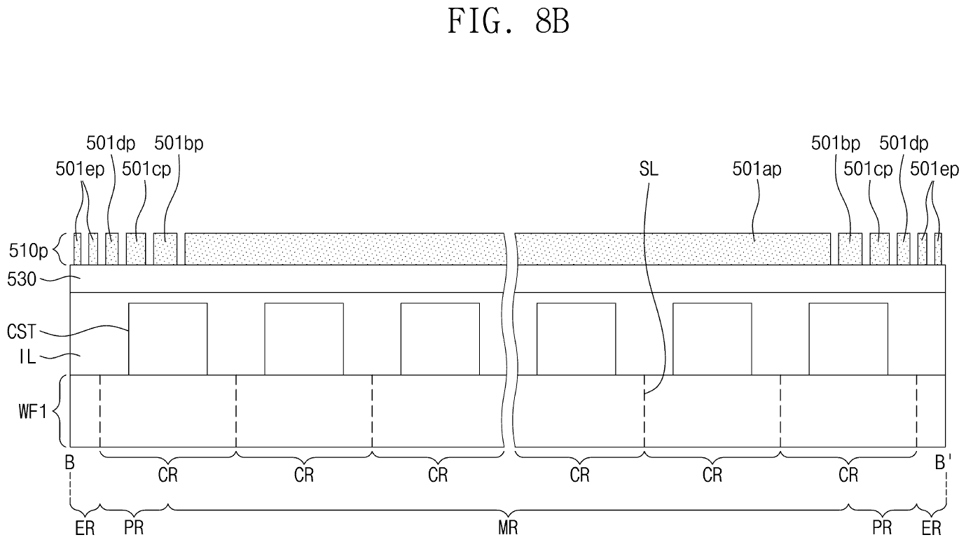

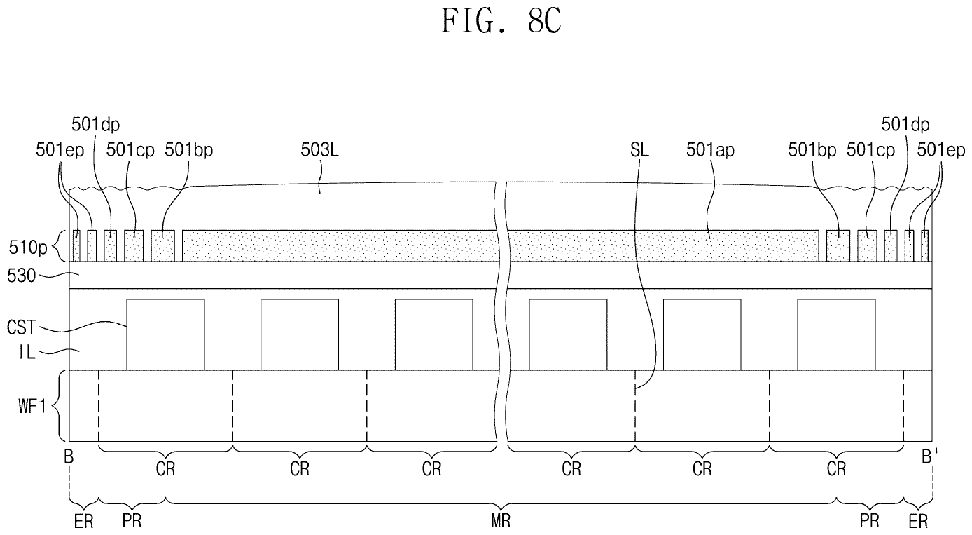

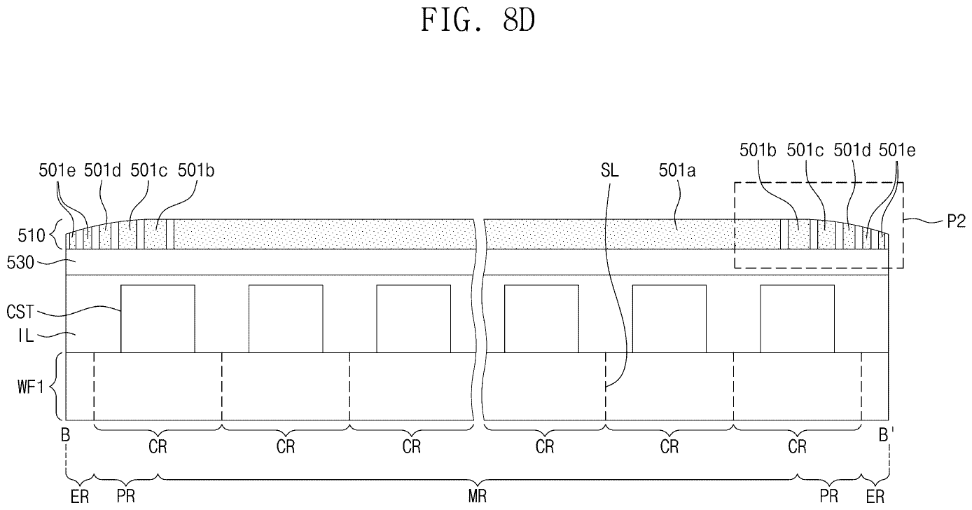

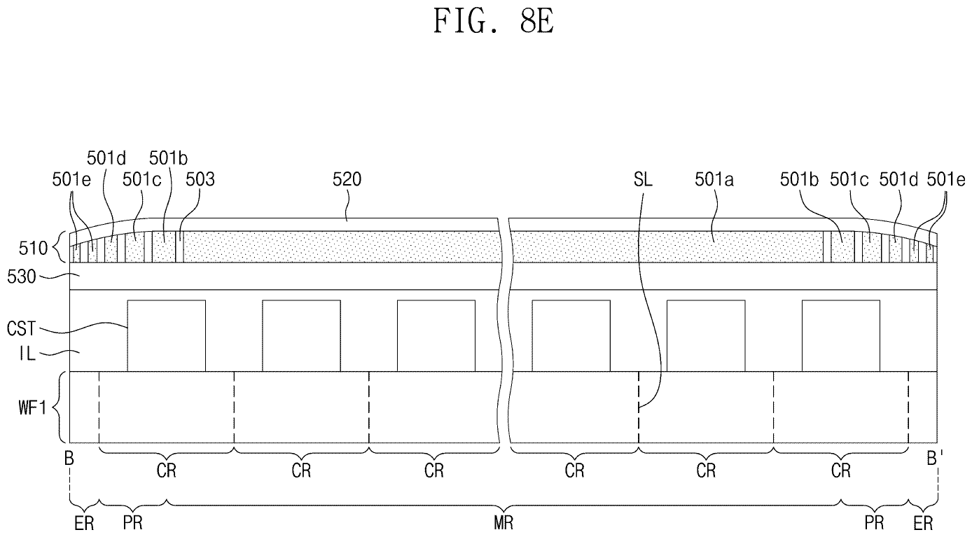

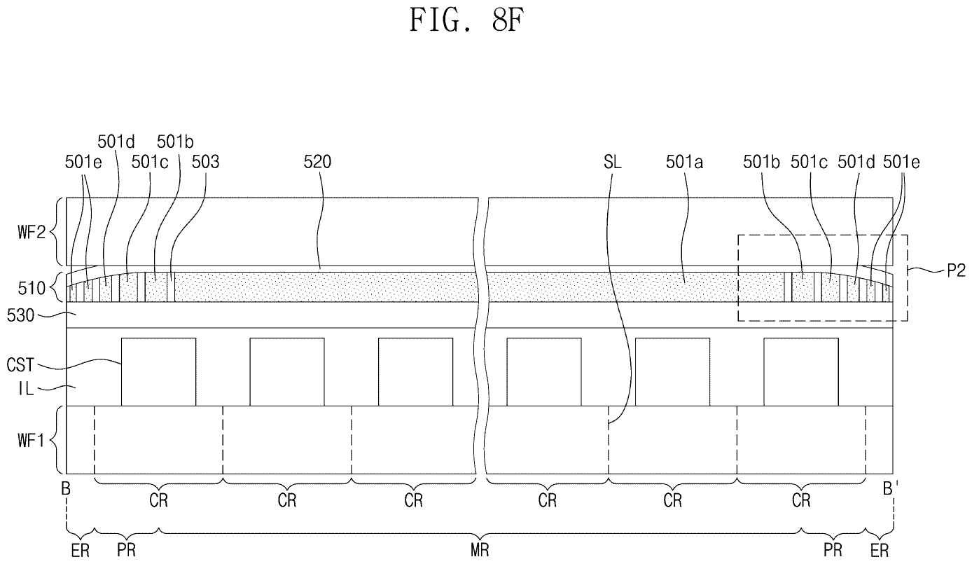

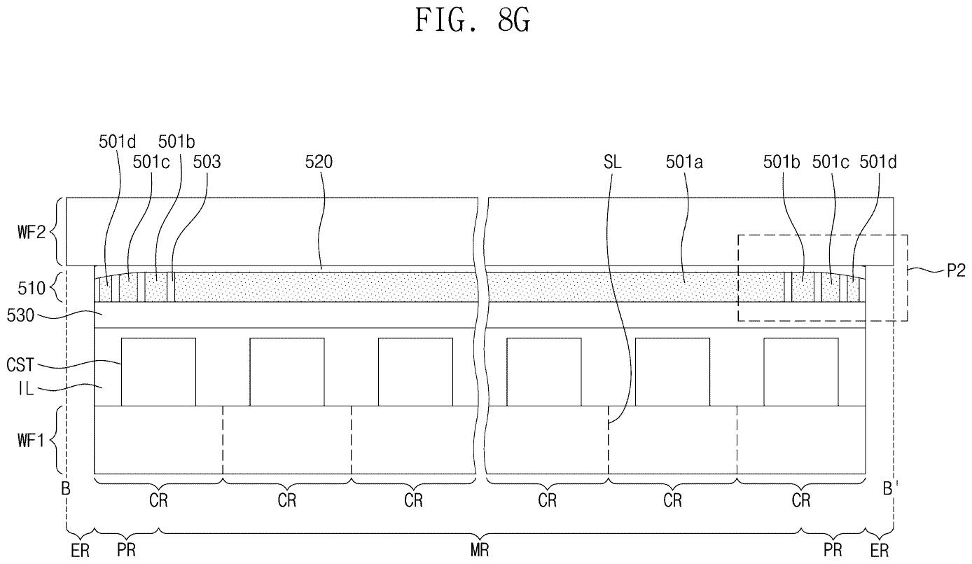

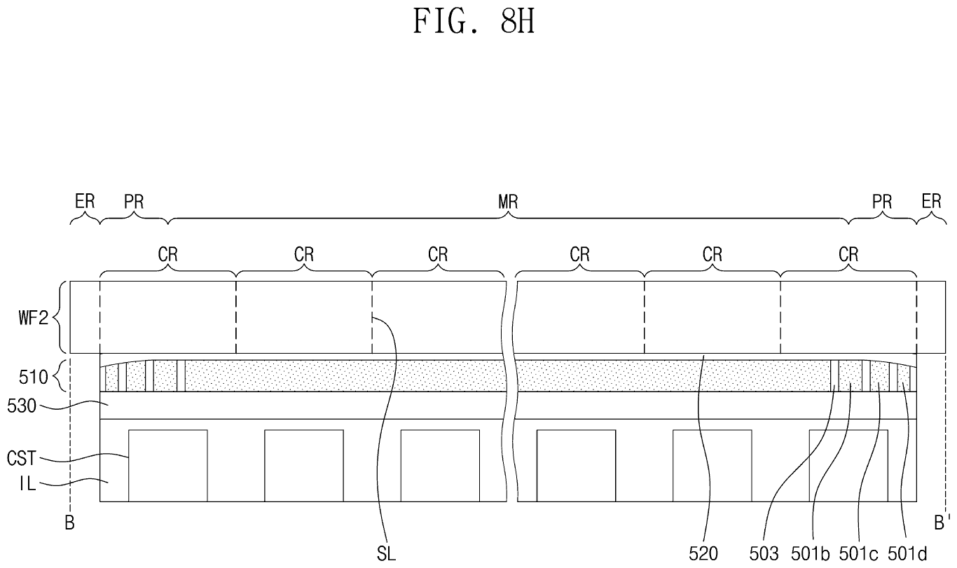

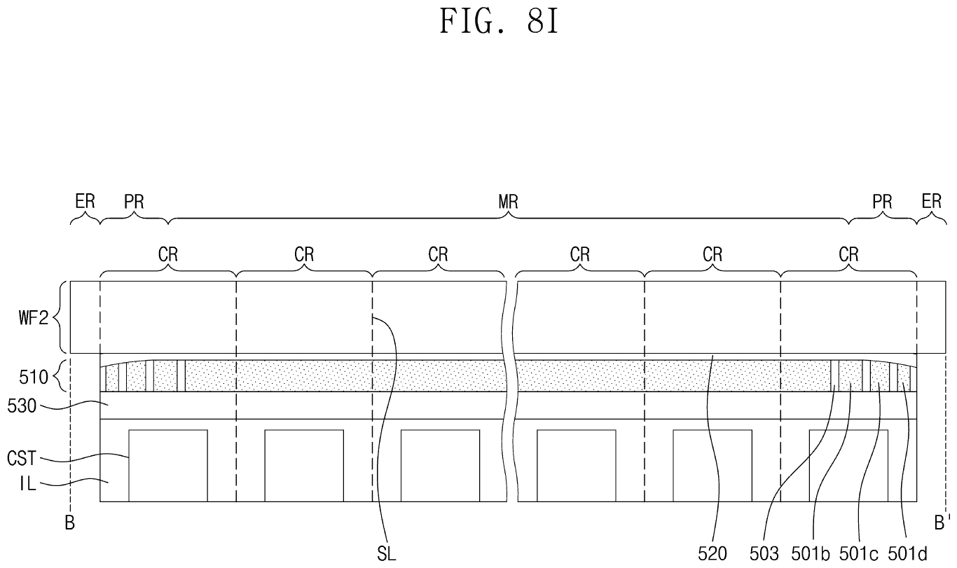

FIGS. 8A to 8I illustrate cross-sectional views showing a method of fabricating a semiconductor device according to some embodiments of the present inventive concepts. FIG. 8A may correspond to a cross section taken along line B-B′ of FIG. 7A or 7B.

Referring to FIG. 8A, first circuit structures CST may be correspondingly formed on the chip regions CR of the first wafer WF1. An interlayer dielectric layer IL may be formed to cover the first circuit structures CST. An upper dielectric layer 530 may be formed on the interlayer dielectric layer IL. The upper dielectric layer 530 may be formed by, for example, supplying tetraethylorthosilicate (TEOS) as a source gas to deposit a silicon oxide layer. The upper dielectric layer 530 may undergo an etch-back process to planarize an upper portion of the upper dielectric layer 530.

FIGS. 9A and 9B illustrate plan views showing polishing barrier patterns formed on a first wafer.

Referring to FIGS. 8B, 9A, and 9B, on the upper dielectric layer 530, a preliminary polishing barrier structure (or a preliminary polishing barrier layer) 510 may be formed to include preliminary first to fifth polishing barrier patterns 501ap to 501ep. The first to fifth preliminary polishing barrier patterns 501ap to 501ep may be formed of a material having a polishing selectivity with respect to the upper dielectric layer 530 and a CMP slurry including, e.g., ceria used in a chemical mechanical polishing (CMP) process. For example, the first to fifth preliminary polishing barrier patterns 501ap to 501ep may be formed of silicon nitride.

An interval between the first to fifth polishing preliminary barrier patterns 501ap to 501ep may be the same as the first interval DS1 discussed with reference to FIGS. 3 to 6E. The first polishing barrier preliminary pattern 501ap may cover the main region MR and have a circular shape when viewed in plan view. The second to fifth preliminary polishing barrier patterns 501bp to 501ep may have a gradation arrangement (gradual variation in shape) as the second to fifth preliminary polishing barrier patterns 501bp to 501ep approach an edge of the first wafer WF1. For example, when viewed in plan view, the first preliminary polishing barrier pattern 501ap may be positioned at the center of the first wafer WF1 and surrounded by the second to fifth preliminary polishing barrier patterns 501bp to 501ep that gradually decrease in size (and/or width) toward the edge of the first wafer WF1. In addition, the first preliminary polishing barrier pattern 501ap may be greater in size than the second preliminary polishing barrier pattern(s) 501bp.

Referring to FIGS. 8B and 9A, each of the second to fifth preliminary polishing barrier patterns 501bp to 501ep may be provided in plural. Each of the second to fifth preliminary polishing barrier patterns 501bp to 501ep may have the same shape (e.g., a tetragonal (or rectangular) shape), but the invention is not limited thereto. For example, the preliminary polishing barrier patterns may have different shapes from each other.

When viewed in plan view, a plurality of any of the second to fifth preliminary polishing barrier patterns 501bp to 501ep may be arranged concentrically, evenly spaced (spaced apart from each other at the same interval in the direction of concentric circles), and uniform in size or shape. The pattern density (i.e., the number of patterns per unit area) of each of the second to fifth preliminary pattern groups may gradually increase toward the edge of the first wafer WF1.

In an embodiment, as illustrated in FIG. 9A, a plurality of subsets SBS of preliminary polishing barrier patterns may be arranged concentrically around the first preliminary polishing barrier pattern 501ap. Each of the plurality of subsets SBS may include the second to fifth preliminary polishing barrier patterns 501bp to 501ep. The plurality of subsets SBS may have substantially the same arrangement of the second to fifth preliminary polishing barrier patterns 501bp to 501ep as each other. When viewed in plan view, the plurality of subsets SBS may be arranged concentrically, evenly spaced (spaced apart from each other at the same interval in the direction of concentric circles), and uniform in size, shape and/or arrangement.

For example, the second to fifth preliminary polishing barrier patterns 501bp to 501ep may have their sizes that decrease with decreasing distance from the edge of the first wafer WF1, and the number of each of the second to fifth preliminary polishing barrier patterns 501bp to 501ep may increase with decreasing distance from the edge of the first wafer WF1. For example, when viewed in plan view, the second preliminary polishing barrier pattern 501bp may surround the first preliminary polishing barrier pattern 501ap. The preliminary second polishing barrier patterns 501bp may have the same size and shape. A constant interval may be provided between the second preliminary polishing barrier patterns 501bp.

As illustrated in FIGS. 8B and 9A, the third preliminary polishing barrier patterns 501cp may be positioned on the peripheral region PR, and may surround the first preliminary polishing barrier pattern 501ap and the preliminary second polishing barrier patterns 501bp. The preliminary third polishing barrier patterns 501cp may have their sizes and widths less than those of the second preliminary polishing barrier patterns 501bp. A pattern density (the number per unit area) of the third preliminary polishing barrier patterns 501cp may be greater than that of the second preliminary polishing barrier patterns 501bp.

As illustrated in FIGS. 8B and 9A, the fourth preliminary polishing barrier patterns 501dp may be positioned on the peripheral region PR, and may surround the first preliminary polishing barrier pattern 501ap, the second preliminary polishing barrier patterns 501bp, and the third preliminary polishing barrier patterns 501cp. The fourth preliminary polishing barrier patterns 501dp may have their sizes and widths less than those of the third preliminary polishing barrier patterns 501cp. A pattern density (the number per unit area) of the preliminary fourth polishing barrier patterns 501dp may be greater than that of the third preliminary polishing barrier patterns 501cp.

As illustrated in FIGS. 8B and 9A, the fifth preliminary polishing barrier patterns 501ep may be positioned on the edge region ER, and may surround the first preliminary polishing barrier pattern 501ap, the second preliminary polishing barrier patterns 501bp, the third preliminary polishing barrier patterns 501cp, and the fourth preliminary polishing barrier patterns 501dp. The fifth preliminary polishing barrier patterns 501ep may have their sizes and widths less than those of the fourth preliminary polishing barrier patterns 501dp. A pattern density (the number per unit area) of the fifth preliminary polishing barrier patterns 501ep may be greater than that of the fourth preliminary polishing barrier patterns 501dp.

Alternatively, referring to FIGS. 8B and 9B, each of the second to fifth preliminary polishing barrier patterns 501bp to 501ep may have a ring shape when viewed in plan view, and may sequentially surround the first preliminary polishing barrier pattern 501ap. The second to fifth preliminary polishing barrier patterns 501bp to 501ep may have their widths that decrease with decreasing distance from the edge of the first wafer WF1. For example, when viewed in plan view, the first preliminary polishing barrier pattern 501ap of the circular shape may be positioned at the center of the first wafer WF1, and surrounded by the ring-like preliminary polishing barrier patterns 501bp to 501ep that gradually decrease in width toward the edge of the first wafer WF1. For example, the second preliminary polishing barrier pattern 501bp may be positioned on an edge of the main region MR. The third and fourth preliminary polishing barrier patterns 501cp and 501dp may be positioned on the peripheral region PR. The fifth preliminary polishing barrier patterns 501ep may be positioned on the edge region ER.

Referring to FIG. 8C, a gap-fill layer 503L may be formed on the first to fifth preliminary polishing barrier patterns 501ap to 501ep. The gap-fill layer 503L may fill a space between the first to fifth preliminary polishing barrier patterns 501ap to 501ep. The gap-fill layer 503L may be formed of a material having a polishing selectivity with respect to the first to fifth preliminary polishing barrier patterns 501ap to 501ep in a chemical mechanical polishing (CMP) process. For example, the gap-fill layer 503L may be removed at a higher rate compared to the preliminary polishing barrier layer 510p under the CMP process such that the selectivity is sufficiently high such that the desirable thickness difference ΔTH (discussed later) may be achieved. The gap-fill layer 503L may be formed by, for example, supplying tetraethylorthosilicate (TEOS) as a source gas to deposit a silicon oxide layer.

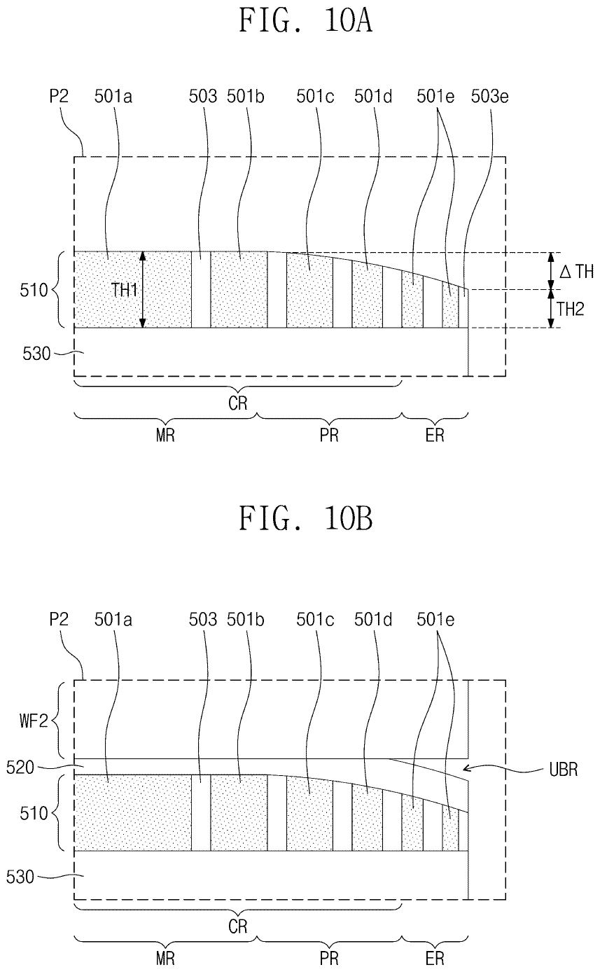

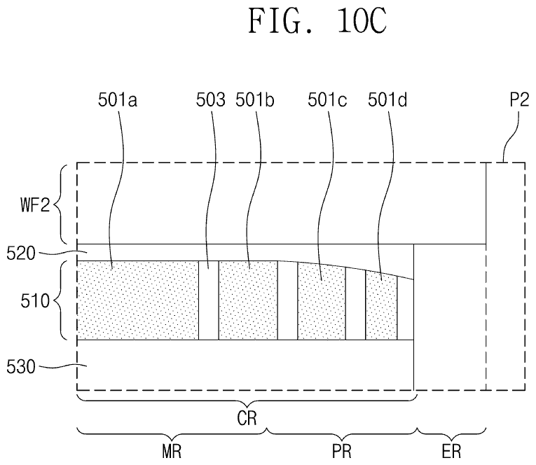

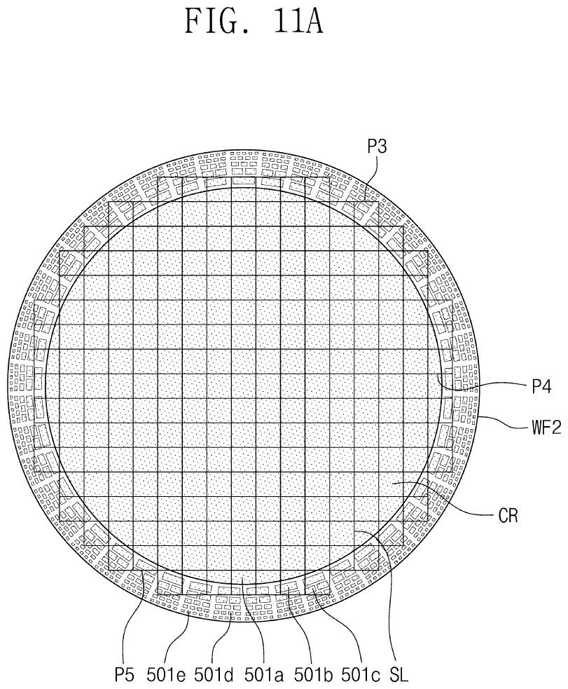

FIG. 10A illustrates an enlarged view showing section P2 of FIG. 8D.

Referring to FIGS. 8D and 10A, the gap-fill layer 503L may undergo a chemical mechanical polishing (CMP) process to expose top surfaces of the first to fifth preliminary polishing barrier patterns 501ap to 501ep and simultaneously to form the gap-fill pattern 503 between the first to fifth polishing barrier patterns 501a to 501e thereby forming a polishing barrier layer (or a polished barrier layer) 510, which includes first to fifth polishing barrier patterns (or a polished barrier patterns) 501a to 501e. In the CMP process, the polishing barrier structure 510 may serve as a CMP barrier layer. In the CMP process, the polishing barrier layer 510 may be used to set the endpoint of polishing (to determine the timing of process termination and/or the material removal amount), e.g., helping to avoid damage to underlying layers by preventing over-polishing. After the CMP process, a roll-off phenomenon may occur to remove or round a portion of an edge of the polishing barrier structure 510, such that the removed or rounded portion is part of a polished barrier structure. The roll-off phenomenon may be an edge effect in the CMP process, where material is removed differently near the wafer edges compared to the other areas (e.g., due to factors such as non-uniform pressure or non-uniform slurry distribution), resulting in non-uniform surface topography. For example, since the first to fifth polishing barrier patterns 501a to 501e have the same interval (the first interval DS1) therebetween, it may be possible to minimize a dishing phenomenon or to suppress a variation in distribution.

The first to fifth polishing barrier patterns 501a to 501e included in the polishing barrier structure 510 may be formed of a material having a polishing selectivity with respect to the gap-fill layer 503L, may have their pattern sizes that decrease with decreasing distance from the edge of the first wafer WF1, and may have their pattern densities that increase with decreasing distance from the edge of the first wafer WF1, with the result that the edge of the polishing barrier structure 510 may be adjusted to achieve a desired degree of roll-off. In addition, pattern sizes and pattern densities of the first to fifth polishing barrier patterns 501a to 501e may be adjusted to control the degree (amount) of roll-off.

For example, the roll-off may be defined to refer to a thickness difference ΔTH between a first thickness TH1 of the first polishing barrier pattern 501a and a second thickness TH2 of the outermost gap-fill pattern 503e. The thickness difference ΔTH may correspond to a height difference between a top surface of the first polishing barrier pattern 501a and the outermost top end of the outermost gap-fill pattern 503e. In the present inventive concepts, the polishing barrier structure 510 may be used to adjust the thickness difference ΔTH to be 4,000 Å to 6,000 Å.

Referring to FIG. 8E, a bonding layer 520 may be deposited on the polishing barrier structure 510. The bonding layer 520 may be formed of, for example, silicon oxide. The bonding layer 520 may undergo a buffering CMP process to control a surface roughness and a local step difference of the bonding layer 520.

FIG. 10B illustrates an enlarged view showing section P2 of FIG. 8F.

Referring to FIGS. 8F and 10B, for example, a thermocompression process may be performed to bond a second wafer WF2 to the bonding layer 520. The second wafer WF2 may be a bare wafer. The second wafer WF2 may have a main region MR, a peripheral region PR, an edge region ER, chip regions CR, and scribe lanes SL whose positions are substantially the same as those of the first wafer WF1 discussed with reference to FIGS. 7A and 7B. After the second wafer WF2 is bonded to the bonding layer 520, an unbonded region UBR may be formed where the bonding layer 520 and the second wafer WF2 are not in contact with each other. An area (or width in a direction parallel to the first and second wafers WF1 and WF2) of the unbonded region UBR may be determined based on the degree of roll-off. The amount of roll-off may vary depending on the arrangement of the polishing barrier patterns, and by controlling the roll-off, it is possible to control how much the unbonded region UBR overlaps with regions MR, PR and ER, as desired. In the present embodiment, the unbonded region UBR may overlap the edge region ER, but may not overlap the peripheral region PR. This may be caused by the fact that the polishing barrier structure 510 is used to reduce the degree of roll-off.

For example, an area (or width) of an unbonded region UBR of FIG. 10B may be in proportion to the degree of roll-off (e.g., the thickness difference ΔTH). In the case of the thickness difference ΔTH is less than 4,000 Å, when a second wafer WF2 is bonded, there may be a high probability of the occurrence of defects (e.g., edge dot voids, or edge bonding voids, which are small, point-like voids near the edge of the die occurred during bonding process) between a bonding layer 520 and a second wafer WF2. The occurrence of edge dot voids may induce cracks when the first wafer WF1 undergoes a grinding process to remove the first wafer WF1 which will be discussed. When the thickness difference ΔTH is greater than 6,000 Å, an unbonded region UBR may become undesirably wide so as to increase the number of the chip regions CR affected by the unboding, thereby leading to a reduction in yield.

In contrast, according to embodiments of the present inventive concepts, since the polishing barrier structure 510 is used to control the thickness difference ΔTH within the range of 4,000 Å to 6,000 Å, the occurrence of edge dot voids may be suppressed to prevent cracks, and simultaneously, the number of the chip regions CR, not affected by the unboding, may be desirably adjusted to achieve an improvement in yield.

FIG. 10C illustrates an enlarged view showing section P2 of FIG. 8G.

Referring to FIGS. 8G and 10C, a laser trimming process may be performed such that the first wafer WF1, the interlayer dielectric layer IL, the upper dielectric layer 530, the fifth polishing barrier patterns 501e of the polishing barrier structure 510, the gap-fill pattern 503 (disposed between the fifth polishing barrier patterns 501e), and the bonding layer 520 may be partially removed to expose a bottom surface of the second wafer WF2. The laser trimming process may remove the unbonded region UBR. In this stage, the fifth polishing barrier patterns 501e may partially remain.

When the polishing barrier structure 510 of the present inventive concepts are not used in a chemical mechanical polishing (CMP) process on an upper dielectric layer, it may be difficult to achieve a desired degree of roll-off such that edge dot voids may be formed to induce cracks in a grinding process. Alternatively, the degree of roll-off may become severe to allow the unbonded region UBR to extend above the peripheral region PR. In this case, however, there may be an increase in amount of the first wafer WF1 (and in amount of its overlying structures) that are needed to be removed in a subsequent laser trimming process, and thus there may be a reduction in the number of the chip regions CR, which may result in a decrease in yield of functional semiconductor dies (or semiconductor chips) on a wafer. In a method of fabricating a semiconductor device according to the present inventive concepts, the polishing barrier structure 510 may be used to reduce the unbonded region UBR, thereby improving a yield.

Referring to FIG. 8H, a grinding process may be performed on the first wafer WF1. Thus, the first wafer WF1 may be removed to expose a bottom surface of the first circuit structure CST and a bottom surface of the interlayer dielectric layer IL. Alternatively, in the grinding process, a portion of the first wafer WF1 may remain such that the portion of the first wafer WF1 may constitute a peripheral substrate 400 of FIG. 5.

In the present inventive concepts, since the unbonded region UBR is removed and then the grinding process is performed, the creation of crack may be prevented.

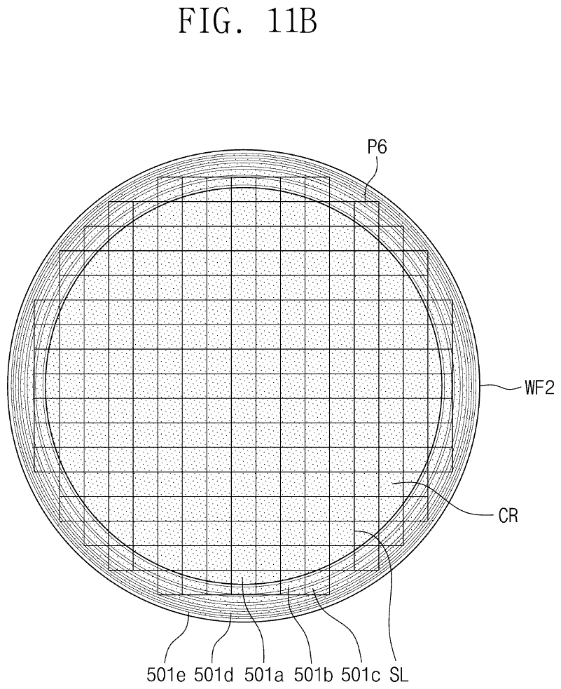

FIGS. 11A and 11B illustrate plan views showing a second wafer when a dicing process is performed.

Referring to FIGS. 8I, 11A, and 11B, a dicing process may be performed along the scribe lanes SL to cut the second wafer WF2 and its underlying bonding layer 520, the polishing barrier structure 510, the upper dielectric layer 530, and the interlayer dielectric layer IL. The semiconductor devices discussed with reference to FIGS. 1 to 5 and 6A to 6E may correspond to the chips formed in the regions CR. In the dicing process, the second wafer WF2 may be cut to serve as a support substrate 600 in the semiconductor devices.

A shape and arrangement of the polishing barrier structure 510 of each of the diced chips (semiconductor devices) may vary depending on their positions within the chip regions CR in the wafer. For example, the fifth direction D5 in FIG. 6B, the second direction D2 in FIG. 6C, the seventh direction D7 in FIG. 6D, and the sixth direction D6 in FIG. 6E may extend along the circumferential direction of the wafer.

In some embodiments, prior to the dicing process, a third wafer may be bonded to the structure described in FIG. 8H. The third wafer may include a plurality of second circuit structures (corresponding to the second subsidiary integrated circuit PST in FIG. 5. In this case, each of the plurality of first subsidiary integrated circuits CST may be formed to include first connection pads (CP1 in FIG. 5), and each of the plurality of second subsidiary integrated circuits may be formed to include second connection pads (CP2 in FIG. 5). The second connection pads may be in contact with corresponding first connection pads such that the first and second subsidiary integrated circuits are electrically connected to each other. Subsequently, the dicing process may be performed to obtain a plurality of integrated circuits as semiconductor devices, in which the first and second subsidiary integrated circuits are electrically connected correspondingly.

In some embodiments, prior to the dicing process, the third wafer may be diced into a plurality of second subsidiary integrated circuits. Subsequently, the plurality of second subsidiary integrated circuits may be bonded such that the second connection pads are in contact with corresponding first connection pads.

For example, the semiconductor device formed with the chip region CR positioned on the main region MR of FIG. 11A may be configured such that the polishing barrier structure 510 is provided in the form of a single plate as illustrated in FIGS. 1 and 6A.

The semiconductor device formed with the chip region CR that corresponds to section P3 of FIG. 11A may be configured such that the polishing barrier structure 510 includes first to fifth polishing barrier patterns 501a to 501e as illustrated in FIGS. 4 and 6B.

The semiconductor device formed with the chip region CR that corresponds to section P4 of FIG. 11A may be configured such that the polishing barrier structure 510 includes first and second polishing barrier patterns 501a and 501b as illustrated in FIG. 6C.

The semiconductor device formed with the chip region CR that corresponds to section P5 of FIG. 11A may be configured such that the polishing barrier structure 510 includes first to third polishing barrier patterns 501a to 501c as illustrated in FIG. 6D.

The semiconductor device formed with the chip region CR that corresponds to section P6 of FIG. 11B, as shown in FIG. 6e, may be configured such that the polishing barrier structure 510 includes first to fifth polishing barrier patterns 501a to 501e. Through the method mentioned above, the semiconductor devices may be fabricated to include the polishing barrier structures 501 have various structures.

No crack may exist in a semiconductor device according to the present inventive concepts, and thus the semiconductor device may have improved reliability. In a method of fabricating a semiconductor device according to the present inventive concepts, a polishing barrier structure may be used to achieve a desired degree of roll-off in a chemical mechanical polishing (CMP) process, such that cracks may be prevented and simultaneously a yield may be improved.

Although the present invention has been described in connection with some embodiments of the present inventive concepts illustrated in the accompanying drawings, it will be understood and apparent to those skilled in the art that various substitution, modifications, and changes may be thereto without departing from the scope and spirit of the present inventive concepts. For example, the embodiments of FIGS. 1 to 6E may be combined with each other.

What is claimed is:

1. A semiconductor device, comprising:
a first subsidiary integrated circuit;
an upper dielectric layer that covers the first subsidiary integrated circuit;
a polished barrier layer on the upper dielectric layer;
a bonding layer on the polished barrier layer; and
a substrate on the bonding layer,
wherein the upper dielectric layer and the bonding layer comprise a first material, and
wherein the polished barrier layer comprises a second material having a polishing selectivity with respect to the first material.

2. The semiconductor device of claim 1, wherein the polished barrier layer comprises a first barrier pattern and a second barrier pattern that are spaced apart from each other,
wherein the first barrier pattern has a first width in a first direction,
wherein the second barrier pattern has a second width in the first direction, the second width being different from the first width, and
wherein the first and second barrier patterns are formed of the second material.

3. The semiconductor device of claim 2, wherein:
the second width is less than the first width,
the first barrier pattern has a first height, and
the second barrier pattern has a second height less than the first height.

4. The semiconductor device of claim 3, wherein the polished barrier layer further comprises a third barrier pattern spaced apart from the first barrier pattern with the second barrier pattern therebetween, and
wherein the third barrier pattern has a third width in the first direction less than the second width and a third height less than the second height.

5. The semiconductor device of claim 2, wherein a height of a selected one from the first and second barrier patterns varies along the first direction.

6. The semiconductor device of claim 2, wherein the polished barrier layer further comprise a first set of barrier patterns and a second set of barrier patterns,
wherein the first and second sets of barrier patterns are formed of the second material, and
wherein each barrier pattern from among the first barrier pattern, the second barrier pattern, the first set of barrier patterns, and the second set of barrier patterns is spaced apart from adjacent barrier patterns from among the first barrier pattern, the second barrier pattern, the first set of barrier patterns, and the second set of barrier patterns at the same interval, in the first direction and in a second direction crossing the first direction.

7. The semiconductor device of claim 2, wherein the polished barrier layer further comprises a gap-fill pattern that fills a space between the first and second barrier patterns, and
wherein the gap-fill pattern comprises the first material.

8. The semiconductor device of claim 2, wherein, when viewed in plan view, each of the first and second barrier patterns has a triangular shape, a rectangular shape, or a pentagonal shape.

9. The semiconductor device of claim 2, wherein the first subsidiary integrated circuit comprises a capacitor that overlaps a selected one from the first barrier pattern and the second barrier pattern.

10. The semiconductor device of claim 1, further comprising a second subsidiary integrated circuit disposed below and electrically connected to the first subsidiary integrated circuit.

11. The semiconductor device of claim 10,
wherein the first subsidiary integrated circuit comprises:
an active pattern elongated in a direction perpendicular to a bottom surface of the substrate and comprising a first end and a second end that are spaced apart from each other,
a word line on a lateral surface of the active pattern and extending in a first direction parallel to the bottom surface of the substrate,
a bit line in contact with the first end of the active pattern and extending in a second direction crossing the first direction, and
a capacitor connected to the second end of the active pattern, and
wherein the second subsidiary integrated circuit comprises a peripheral transistor connected to the word line or the bit line.

12. A semiconductor device, comprising:
a first subsidiary integrated circuit;
an upper dielectric layer that covers the first subsidiary integrated circuit;
a polished barrier layer on the upper dielectric layer;
a bonding layer on the polished barrier layer; and
a substrate on the bonding layer,
wherein the polished barrier layer comprises a first barrier pattern and a second barrier pattern that are spaced apart from each other,
wherein the first barrier pattern has a first width in a first direction, and
wherein the second barrier pattern has a second width in the first direction, the second width being different from the first width.

13. The semiconductor device of claim 12, wherein:
the second width is less than the first width,
the first barrier pattern has a first height, and
the second barrier pattern has a second height less than the first height.

14. The semiconductor device of claim 13, wherein the polished barrier layer further comprises a third barrier pattern spaced apart from the first barrier pattern with the second barrier pattern therebetween, and
wherein the third barrier pattern has a third width in the first direction less than the second width and a third height less than the second height.

15. The semiconductor device of claim 12, wherein a height of a selected one from the first barrier pattern and the second barrier pattern varies along the first direction.

16. The semiconductor device of claim 12, wherein the polished barrier layer further comprises a first set of barrier patterns and a second set of barrier patterns,
wherein the first and second sets of barrier patterns are formed of a first material, and
wherein each barrier pattern from among the first barrier pattern, the second barrier pattern, the first set of barrier patterns, and the second set of barrier patterns is spaced apart from adjacent barrier patterns from among the first barrier pattern, the second barrier pattern, the first set of barrier patterns, and the second set of barrier patterns at the same interval, in the first direction and in a second direction crossing the first direction.

17. The semiconductor device of claim 12, wherein the polished barrier layer further comprises a gap-fill pattern that fills a space between the first and second barrier patterns,
wherein the upper dielectric layer, the bonding layer, and the gap-fill pattern comprise a first material, and
wherein each of the first barrier pattern and the second barrier pattern comprises a second material having a polishing selectivity with respect to the first material.

18. A semiconductor device, comprising:
a subsidiary integrated circuit;
an upper dielectric layer that covers the subsidiary integrated circuit;
a polished barrier layer on the upper dielectric layer;
a bonding layer on the polished barrier layer; and
a substrate on the bonding layer,
wherein the subsidiary integrated circuit comprises:
an active pattern elongated in a direction perpendicular to a bottom surface of the substrate and comprising a first end and a second end that are spaced apart from each other,
a word line on a lateral surface of the active pattern and extending in a first direction parallel to the bottom surface of the substrate,
a bit line connected to the first end of the active pattern and extending in a second direction crossing to the first direction, and
a capacitor connected to the second end of the active pattern,
wherein the polished barrier layer comprises a plurality of barrier patterns that are spaced apart from each other, the plurality of barrier patterns including first barrier patterns and second barrier patterns, wherein each barrier pattern is spaced apart from adjacent barrier patterns,
wherein each of the first barrier patterns has a first width,
wherein each of the second barrier patterns has a second width different from the first width,
wherein the capacitor overlaps at least one barrier pattern selected from the plurality of barrier patterns, and
wherein the plurality of barrier patterns are spaced apart from each other at the same interval.

19. The semiconductor device of claim 18, wherein a height of a selected one barrier pattern of the plurality of barrier patterns varies along a first direction extending along the substrate.

20. The semiconductor device of claim 18, wherein the polished barrier layer further comprises a gap-fill pattern that fills a space between adjacent barrier patterns among the first barrier patterns and the second barrier patterns,
wherein the upper dielectric layer, the bonding layer, and the gap-fill pattern comprise a first material, and
wherein each barrier pattern of the plurality of barrier patterns comprises a second material having a polishing selectivity with respect to the first material.

21. A method of fabricating a semiconductor device, the method comprising:
manufacturing a plurality of subsidiary integrated circuits on a first wafer that comprise a main region, a peripheral region that surrounds the main region, and an edge region that surrounds the peripheral region;
forming on the first wafer an upper dielectric layer that covers the plurality of subsidiary integrated circuits;
forming a preliminary polishing barrier layer on the upper dielectric layer, wherein the preliminary polishing barrier layer comprises a plurality of first preliminary barrier patterns on the main region, a plurality of second preliminary barrier patterns on the peripheral region, and a plurality of third preliminary barrier patterns on the edge region;
forming a gap-fill layer to fill a space between the first, second, and third preliminary barrier patterns, the gap-fill layer covering the preliminary polishing barrier layer;
performing a chemical mechanical polishing process to partially remove the gap-fill layer on the preliminary polishing barrier layer and to form polished barrier layer including first, second, and third barrier patterns, and to form a plurality of gap-fill patterns between the first, second, and third barrier patterns;
stacking a bonding layer on the polished barrier layer;
bonding a second wafer to the bonding layer;
performing a trimming process to remove the edge region of the first wafer, the upper dielectric layer that overlaps the edge region of the first wafer, portions of the third barrier patterns and the gap-fill patterns, and a portion of the bonding layer; and
removing the first wafer.

22. The method of claim 21, further comprising performing a dicing process on the second wafer.

23. The method of claim 21, wherein the first, second, and third barrier patterns are spaced apart from each other at the same interval in first and second directions crossing each other.

24. The method of claim 21, wherein:
each of the first barrier patterns has a first width,
each of the second barrier patterns has a second width less than the first width, and
each of the third barrier patterns has a third width less than the second width.

25. The method of claim 21, wherein:
the upper dielectric layer, the bonding layer, and the gap-fill layer comprise a first material, and
each barrier pattern of the first barrier patterns and the second barrier patterns comprises a second material having a polishing selectivity with respect to the first material.
